(19) United States
(12) Patent Application Publication
(10) Pub. No.: US 2026/0096165 A1
(43) Pub. Date: Apr. 2, 2026

(54) SEMICONDUCTOR DEVICE

(71) Applicant: Infineon Technologies Austria AG, Villach (AT)

(72) Inventors: Enrique VECINO-VAZQUEZ, München (DE); David CASTILLA ARAGON, Villach (AT)

(21) Appl. No.: 18/901,845

(22) Filed: Sep. 30, 2024

(51) Int. Cl. H01L 29/08; H01L 29/417

(52) U.S. Cl. CPC H10D 62/151; H10D 64/257; H10D 64/258

(57) ABSTRACT

According to some embodiments, a device is provided. The device includes a transistor having a gate electrode, a first gate pad connected to the gate electrode, a second gate pad connected to the gate electrode, and a first gate ring connecting the first gate pad and the second gate pad.

### TECHNICAL FIELD

The present disclosure relates to semiconductor devices, for example to silicon carbide (SiC) semiconductor devices and manufacturing methods therefore.

### BACKGROUND

Semiconductor devices include doped regions formed by ion implantation. Semiconductor dies containing semiconductor devices are mounted in device packages with external contact pads for accessing the semiconductor devices in the dies.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, a device is provided. The device comprises a transistor comprising a gate electrode, a first gate pad connected to the gate electrode, a second gate pad connected to the gate electrode, and a first gate ring connecting the first gate pad and the second gate pad.

According to some embodiments, a circuit board assembly is provided. The circuit board assembly comprises a first semiconductor package comprising a first semiconductor die, the first semiconductor die comprises a first gate pad, a second gate pad, and a first gate ring connecting the first gate pad to the second gate pad. The circuit board assembly comprises a second semiconductor package comprising a second semiconductor die, the second semiconductor die comprises a third gate pad, a fourth gate pad, and a second gate ring connecting the third gate pad to the fourth gate pad. The circuit board assembly comprises a gate pin, and a gate interconnect connecting the gate pin to the first gate pad and the third gate pad.

According to some embodiments, a method is provided. The method comprises mounting a first semiconductor die in a first semiconductor package, the first semiconductor die comprises a first gate pad, a second gate pad, and a first gate ring connecting the first gate pad to the second gate pad. The method comprises mounting a second semiconductor die in a second semiconductor package, the second semiconductor die comprises a third gate pad, a fourth gate pad, and a second gate ring connecting the third gate pad to the fourth gate pad. The method comprises connecting a gate pin to the first gate pad and the third gate pad.

According to some embodiments, a system is provided. The system comprises means for mounting a first semiconductor die in a first semiconductor package, the first semiconductor die comprises a first gate pad, a second gate pad, and a first gate ring connecting the first gate pad to the second gate pad. The system comprises means for mounting a second semiconductor die in a second semiconductor package, the second semiconductor die comprises a third gate pad, a fourth gate pad, and a second gate ring connecting the third gate pad to the fourth gate pad. The system comprises means for connecting a gate pin to the first gate pad and the third gate pad.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a plan view of a semiconductor device, in accordance with some embodiments.

FIG. 2 is a cross-section view of a semiconductor device, in accordance with some embodiments.

FIGS. 3-11 are plan views of arrangements for interconnecting semiconductor packages including one or more semiconductor devices, according to some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

The term “over” and/or “overlying” is not to be construed as meaning only “directly over” and/or “having direct contact with”. Rather, if one element is “over” and/or “overlying” another element (e.g., a region is overlying another region), a further element (e.g., a further region) may be positioned between the two elements (e.g., a further region may be positioned between a first region and a second region if the first region is “over” and/or “overlying” the second region). Further, if a first element is “over” and/or “overlying” a second element, at least some of the first element may be vertically coincident with the second element, such that a vertical line may intersect the first element and the second element.

The semiconductor substrate or body may extend along a main extension plane. The term “horizontal” as used in this specification intends to describe an orientation substantially parallel to said main extension plane. A first or main horizontal side of the semiconductor substrate or body may run substantially parallel to horizontal directions or may have surface sections that enclose an angle of at most 8° (or at most 6° or at most 4°) with the main extension plane. The first or main horizontal side can be for instance the surface of a wafer or a die. Sometimes, the horizontal direction is also referred to as lateral direction.

The term “vertical” as used in this specification intends to describe an orientation which is substantially arranged perpendicular to the horizontal direction, (e.g., parallel to the normal direction of the first side of the semiconductor substrate or body or parallel to the normal direction of a surface section of the first side of the semiconductor substrate or body).

The Figures illustrate relative doping concentrations by indicating "-" or "+" next to the dopant conductivity type "n" or "p". For example, "n-" means a dopant concentration which is lower than the dopant concentration of an "n" doped region while an "n+" doped region has a higher dopant concentration than an "n" doped region. Doped regions of the same relative dopant concentration do not necessarily have the same absolute dopant concentration. For example, two different "n" doped regions may have the same or different absolute dopant concentrations. In some embodiments, n-type dopants (or impurities) may include at least one of phosphorous, arsenic, or another suitable n-type dopants, and p-type dopants (or impurities) may include at least one of boron, BF₃, or other suitable p-type dopants.

In accordance with the present disclosure, a semiconductor device and a method of manufacturing the semiconductor device are provided. The embodiments described herein may be combined in any way.

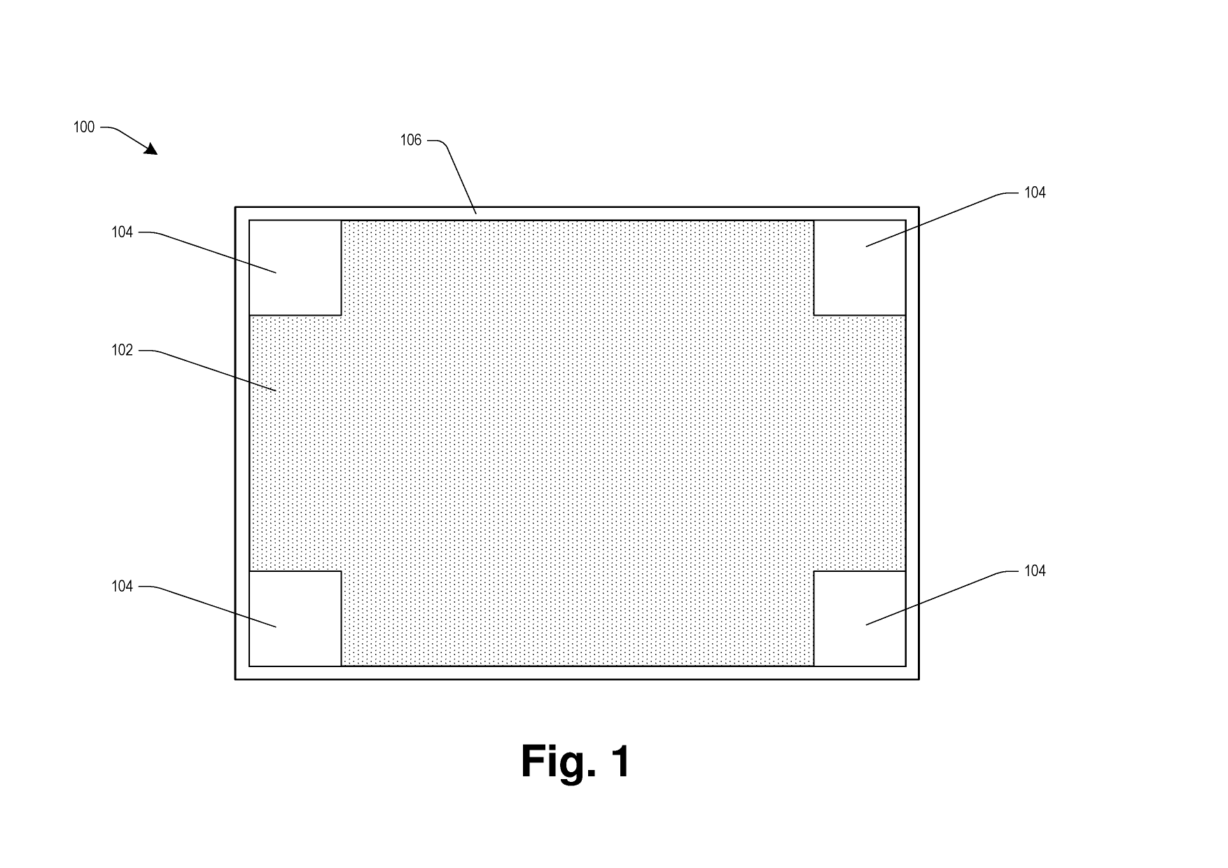

FIG. 1 is a plan view of a semiconductor device 100 is provided, according to some embodiments. In some embodiments, the semiconductor device 100 is a super-junction transistor device including a source pad 102 with an underlying source semiconductor structure, gate pads 104 with an underlying gate semiconductor structure, and a gate ring 106 in an edge termination region of the semiconductor device 100. The gate ring 106 interconnects the gate pads 104. In some embodiments, a drain pad for contacting the drain of the transistor is on a back side of the semiconductor device 100. The semiconductor device 100 may be a semiconductor die. The number and placement of the gate pads 104 may vary.

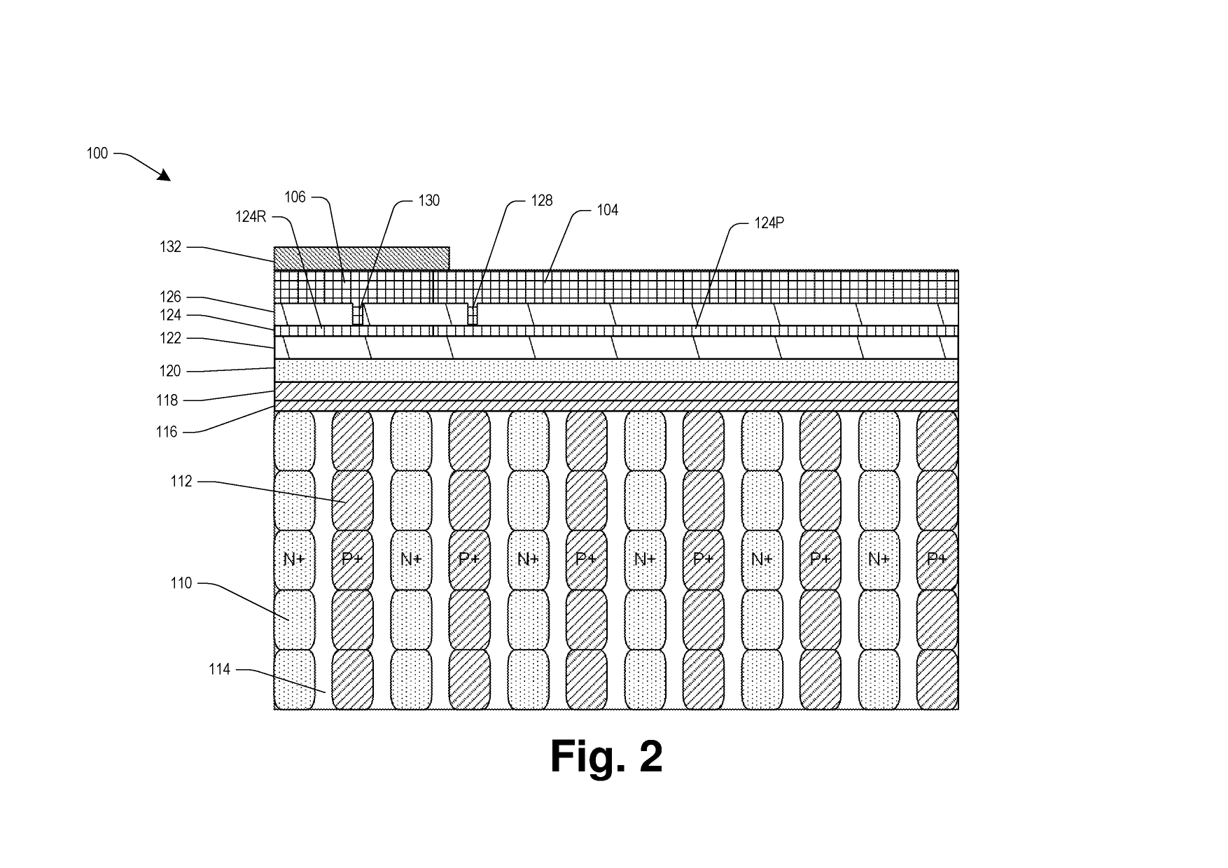

FIG. 2 is a cross-section of a portion of the semiconductor device 100 illustrating the gate pad 104 and the gate ring 106, in accordance with some embodiments. The semiconductor device 100 comprises highly doped n-pillars 110 and highly doped p-pillars 112 in a semiconductor body 114. In some embodiments, the semiconductor body 114 comprises crystalline semiconductor material, such as silicon carbide (SiC) and/or other semiconductor compounds.

P-doped semiconductor layers 116, 118 and an n-doped semiconductor layer 120 are formed over the pillars 110, 112 to control the electric field and to aid the recombination of carriers during commutation events. A gate dielectric layer 122, such as a form of silicon dioxide, is formed over the n-doped semiconductor layer 120, and a gate electrode layer 124, such as polysilicon, is formed over the gate dielectric layer 122. In some embodiments, the gate electrode layer 124 comprises a gate electrode pad portion 124P under and having the same general shape as the gate pad 104 and a gate electrode ring portion 124R under and having the same general shape as the gate ring 106. A dielectric layer 126 is formed over the gate electrode layer 124. Conductive vias 128 connect the gate pad 104 to the gate electrode pad portion 124P of the gate electrode layer 124 and conducive vias 130 connect the gate ring 106 to the gate electrode ring portion 124R of the gate electrode layer 124. The conductive vias 128, 130 may be positioned around the periphery of the semiconductor device 100 such that each gate pad 104 has a corresponding underlying gate electrode pad portion 124P and multiple conductive vias 128. Similarly, the gate ring 106 may have an underlying gate electrode ring portion 124R with multiple connecting vias 130. In some embodiments, a protective layer 132, such as a polyimide layer, is formed over the semiconductor device 100 and patterned for form an opening over the gate pad 104 while covering the gate ring 106. In some embodiments, the vias 128, 130 comprise tungsten or some other conductive material. The gate pads 104 and the gate ring may comprise multiple layers, such as a tungsten later that includes the vias 128, 130 and one or more additional layer, such as an aluminum copper layer. In some embodiments, the protective layer covers some portions of the source pad 102 while other portions of the source pad 102 exposed to allow connection thereto.

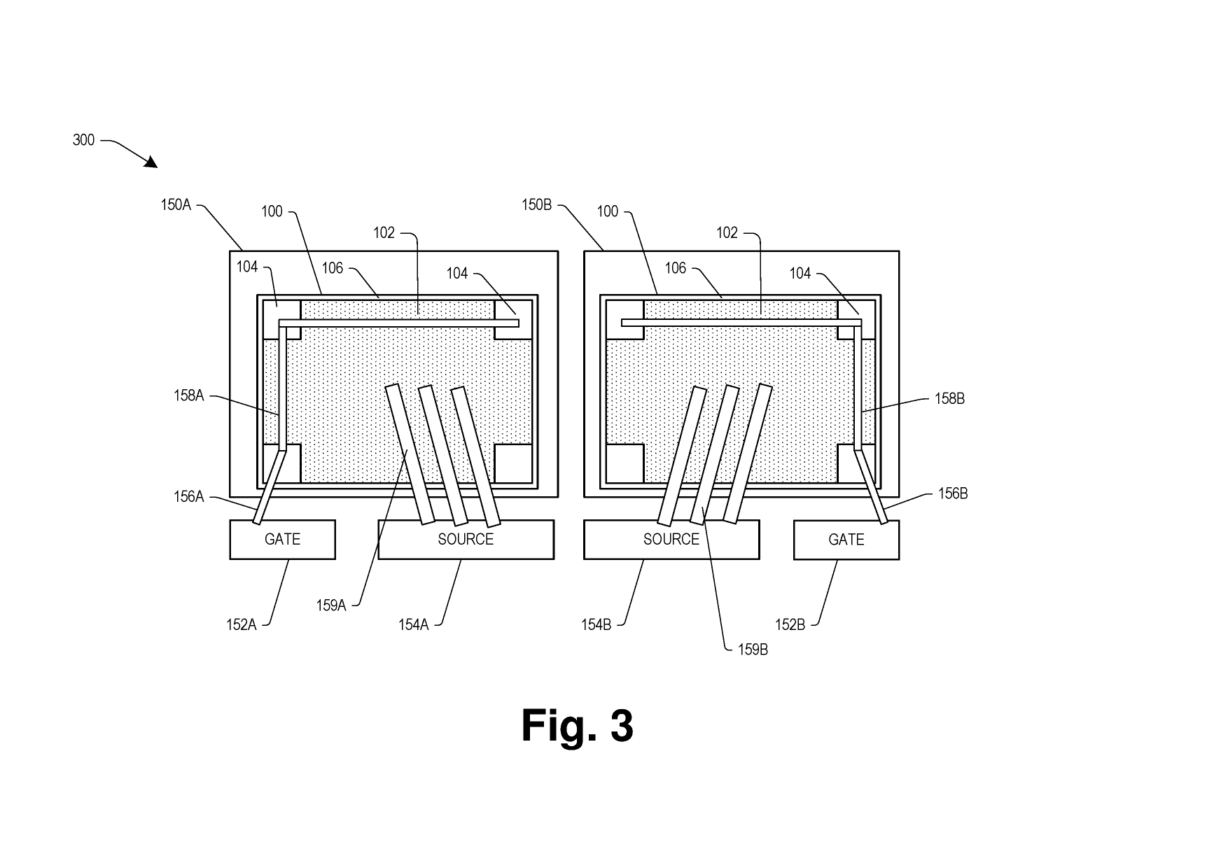

FIGS. 3-11 are plan views of arrangements of a circuit board assembly for interconnecting semiconductor packages including the semiconductor device 100, according to some embodiments. The views of FIGS. 3-11 are simplified in that the protective layer 132 with openings exposing portions of the source pad 102 and openings exposing the gate pads 104 is omitted. The views of FIGS. 3-11 also include semiconductor packages which may have additional protective layers (not shown) with patterned openings to facilitate the interconnections illustrated.

Referring to FIG. 3, a circuit board assembly 300 comprises semiconductor packages 150A, 150B including instances of the semiconductor device 100 interface with gate pins 152A, 152B and source pins 154A, 154B. In the embodiment of FIG. 6, the semiconductor device 100 comprises four gate pads 104 connected by the gate ring 106. In some embodiments, gate interconnects 156A, 156B connect the gate pins 152A, 152B to a selected gate pad 104 of the semiconductor device 100 and gate interconnects 158A, 158B interconnect two or more of the gate pads 104. The interconnects may be conductive traces, bond wires, flowable conductive materials, plates, or some other type of conductive interconnect. Providing the gate interconnects 158A, 158B reduces the signal propagation time for the gate signal and improves signal distribution. In some embodiments, source interconnects 159A, 159B connect the source pins 154A, 154B to respective the source pad 102 of the semiconductor device 100. Providing the gate pads 104 are various locations on the semiconductor device 100 provides flexibility regarding the contact locations to maintain adherence to manufacturability and design rules. For example, the gate interconnects 156A are on the opposite side of the semiconductor package 150A compared to the gate interconnects 156B on the semiconductor package 150B.

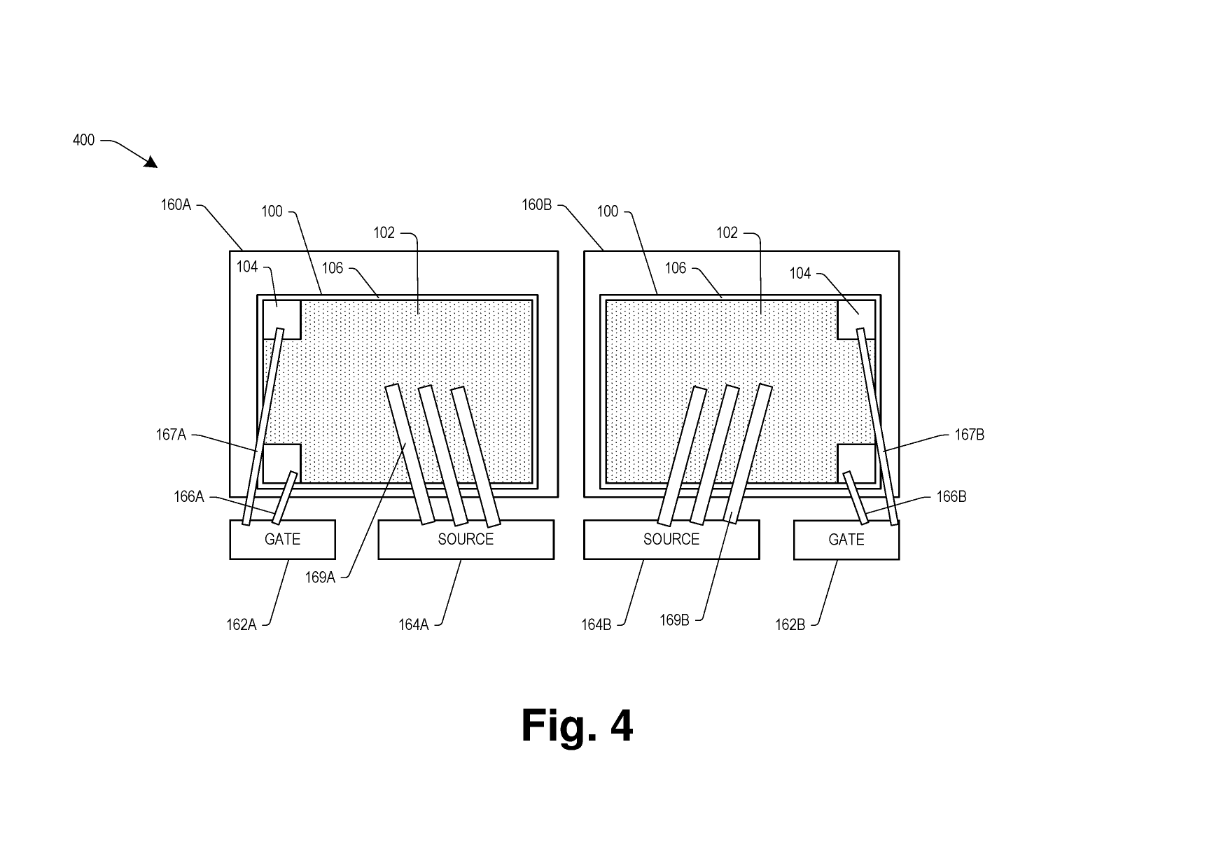

Referring to FIG. 4, a circuit board assembly 400 comprises semiconductor packages 160A, 160B including instances of the semiconductor device 100 interface with gate pins 162A, 162B and source pins 164A, 164B. In the embodiment of FIG. 4, the semiconductor device 100 comprises two gate pads 104 connected by the gate ring 106. Note that the semiconductor package 160B is rotated by 180° with respect to the semiconductor package 160A to provide flexibility for the contacts. To reduce gate signal propagation delay by providing earlier activation of the gate ring 106, separate gate interconnects 166A, 167A connect the gate pin 162A to the gate pads 104 of the semiconductor device 100 in the semiconductor package 160A and separate gate interconnects 166B, 167B connect the gate pin 162B to the gate pads 104 of the semiconductor device 100 in the semiconductor package 160B. In some embodiments, source interconnects 169A, 169B connect the source pins 164A, 164B to the respective source pad 102 of the semiconductor device 100.

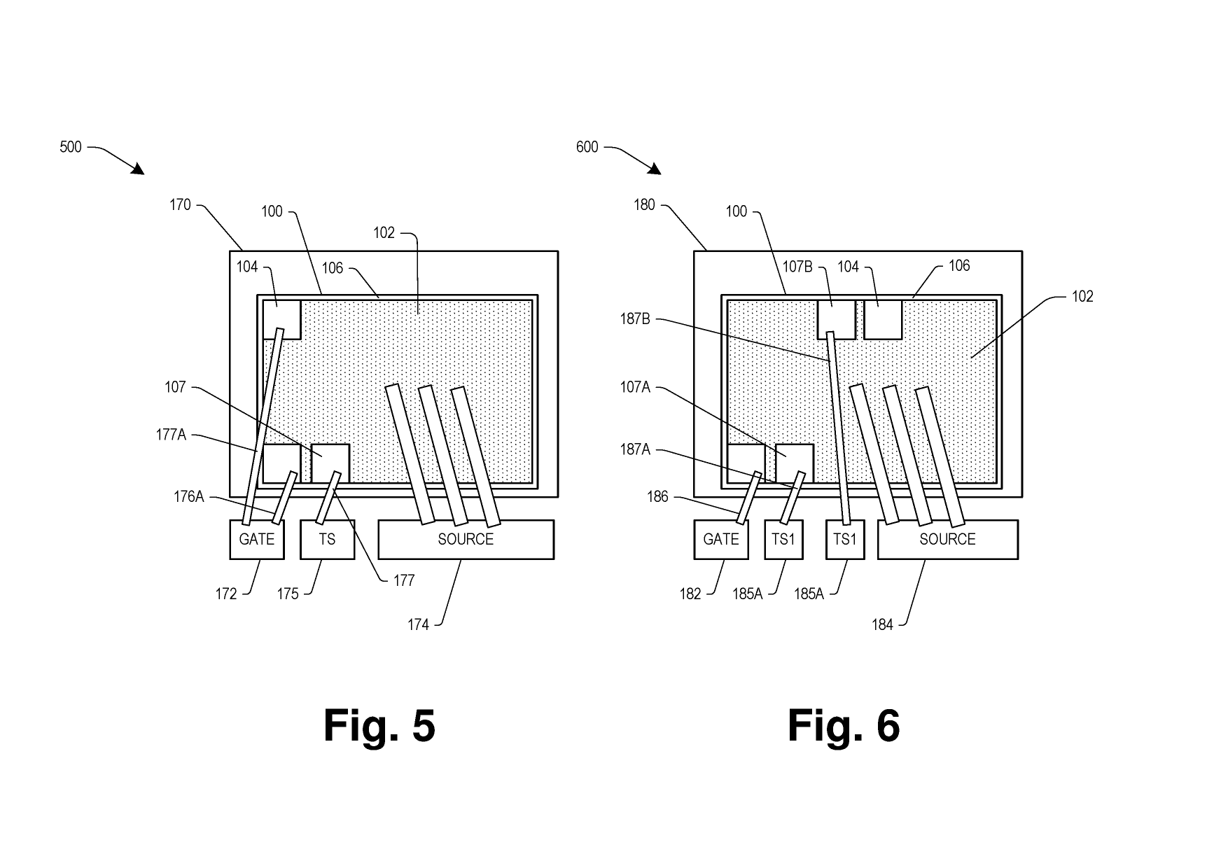

Referring to FIG. 5, a circuit board assembly 500 comprises a semiconductor package 170 including an instance of the semiconductor device 100 interfaces with a gate pin 172, a source pin 174, and a temperature sense (TS) pin 175. In the embodiment of FIG. 5, the semiconductor device 100 comprises two gate pads 104 connected by the gate ring 106 and a temperature sense pad 107 to facilitate measuring the temperature of the semiconductor package 170. One or more gate interconnects 176A, 177A connect the gate pin 172A to the gate pads 104 of the semiconductor device 100 in the semiconductor package 160A and a TS interconnect 177 connects the temperature sense pin 175 to the TS pad 107 of the semiconductor device 100 in the semiconductor package 170. In some embodiments, source interconnects 179 connect the source pin 174 to the source pad 102 of the semiconductor device 100.

Referring to FIG. 6, a circuit board assembly 600 comprises a semiconductor package 180 including an instance of the semiconductor device 100 interfaces with a gate pin 182, a source pin 184, and multiple temperature sense pin 185A, 185B. In the embodiment of FIG. 6, the semiconductor device 100 comprises two gate pads 104 connected by the gate ring 106 and two temperature sense pads 107A 107B to facilitate measuring the temperature of the semiconductor package 180 in different locations. Note that one of the gate pads 104 is located in a center of the semiconductor device 100 rather than the corner. A gate interconnects 186 connects the gate pin 182 to the gate pad 104 of the semiconductor device 100 in the semiconductor package 180 and TS interconnects 187A, 187B connect the temperature sense pins 185A, 185B to the TS pads 107A, 107B of the semiconductor device 100 in the semiconductor package 180. In some embodiments, source interconnects 189 connect the source pin 184 to the source pad 102 of the semiconductor device 100.

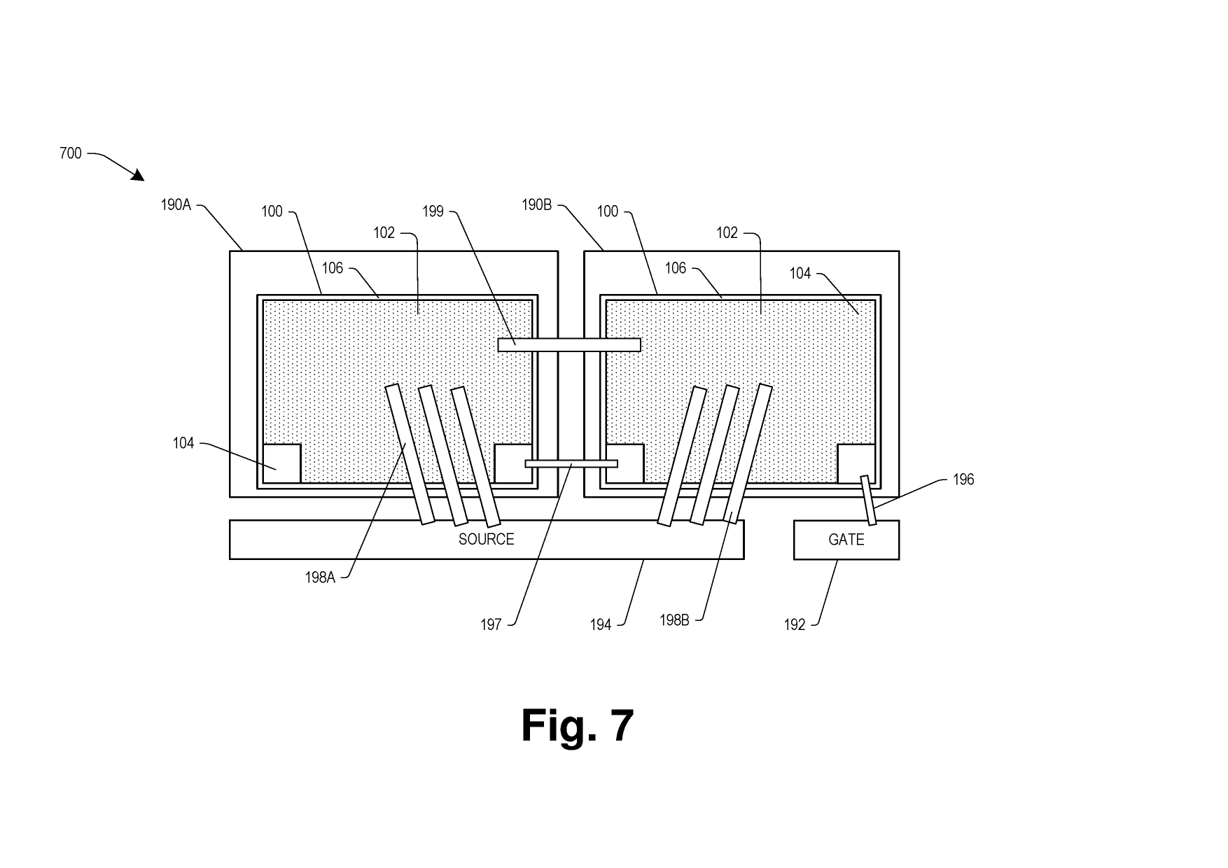

Referring to FIG. 7, a circuit board assembly 700 comprises semiconductor packages 190A, 190B including instances of the semiconductor device 100 interface with a gate pin 192 and a source pin 194 such that the semiconductor devices 100 in the semiconductor packages 190A, 190B are interconnected and operated in parallel. In the embodiment of FIG. 7, the semiconductor devices 100 each comprises two gate pads 104 connected by the gate ring 106. A gate interconnect 196 connects the gate pin 192 to the gate pad 104 of the semiconductor device 100 in the semiconductor package 190B and a gate interconnect 197 connects the a gate pad 104 of the semiconductor device 100 in the semiconductor package 190B to an adjacent gate pad 104 of the semiconductor device 100 in the semiconductor package 190A. In some embodiments, source interconnects 198A, 199B connect the source pin 194 to the respective source pads 102 of the semiconductor devices 100 in the semiconductor packages 190A, 190B. In some embodiments, an additional source interconnect 199 directly connects the respective source pads 102 of the semiconductor devices 100 in the semiconductor packages 190A, 190B to reduce asymmetric source bonding to ground.

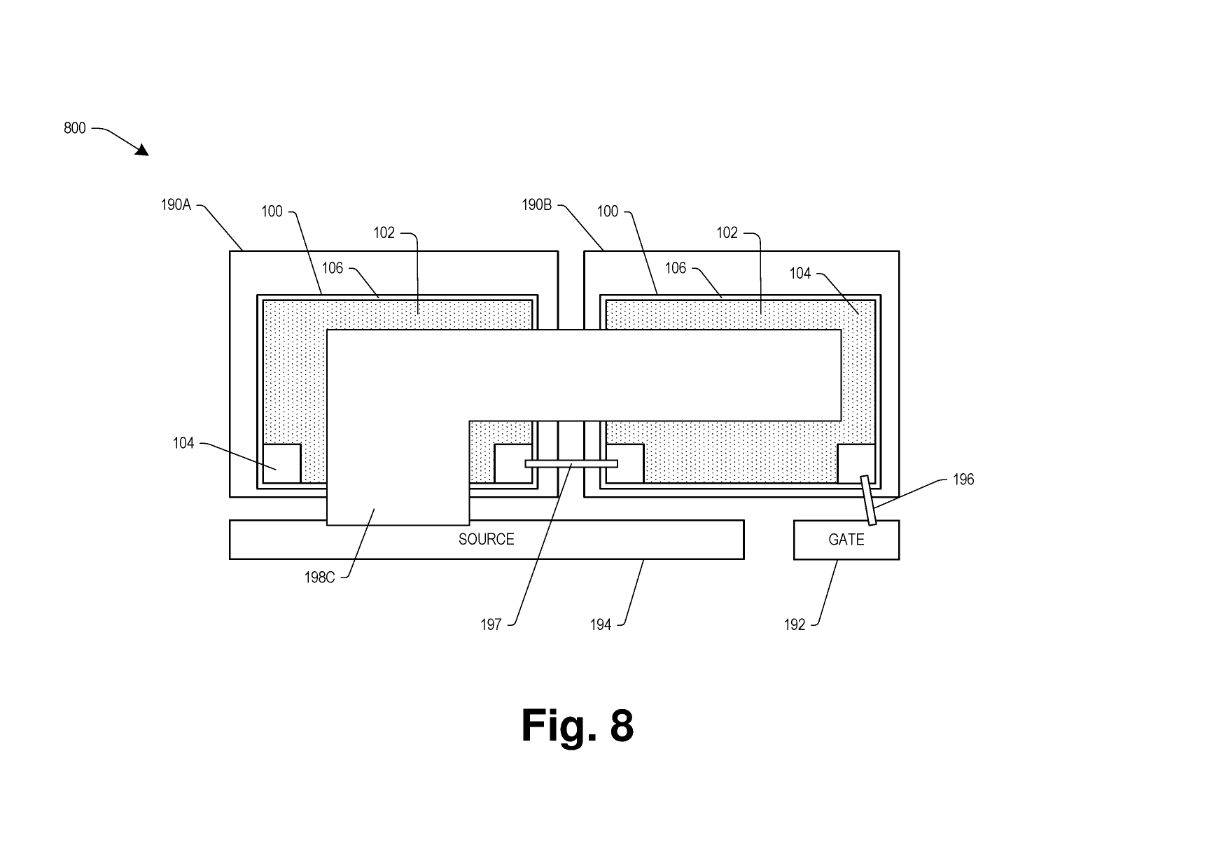

Referring to FIG. 8, a circuit board assembly 800 is illustrated where the source interconnects 198A, 198B, 199 illustrated in FIG. 7 are replaced by a source interconnect clip 198C contacting and interconnecting the respective source pads 102 of the semiconductor devices 100 in the semiconductor packages 190A, 190B. In some embodiments, the clip 198C may comprise a conductive material, such as copper, aluminum, a metal alloy, or some other conductive material. The clip 198C may be plated with a solderable material.

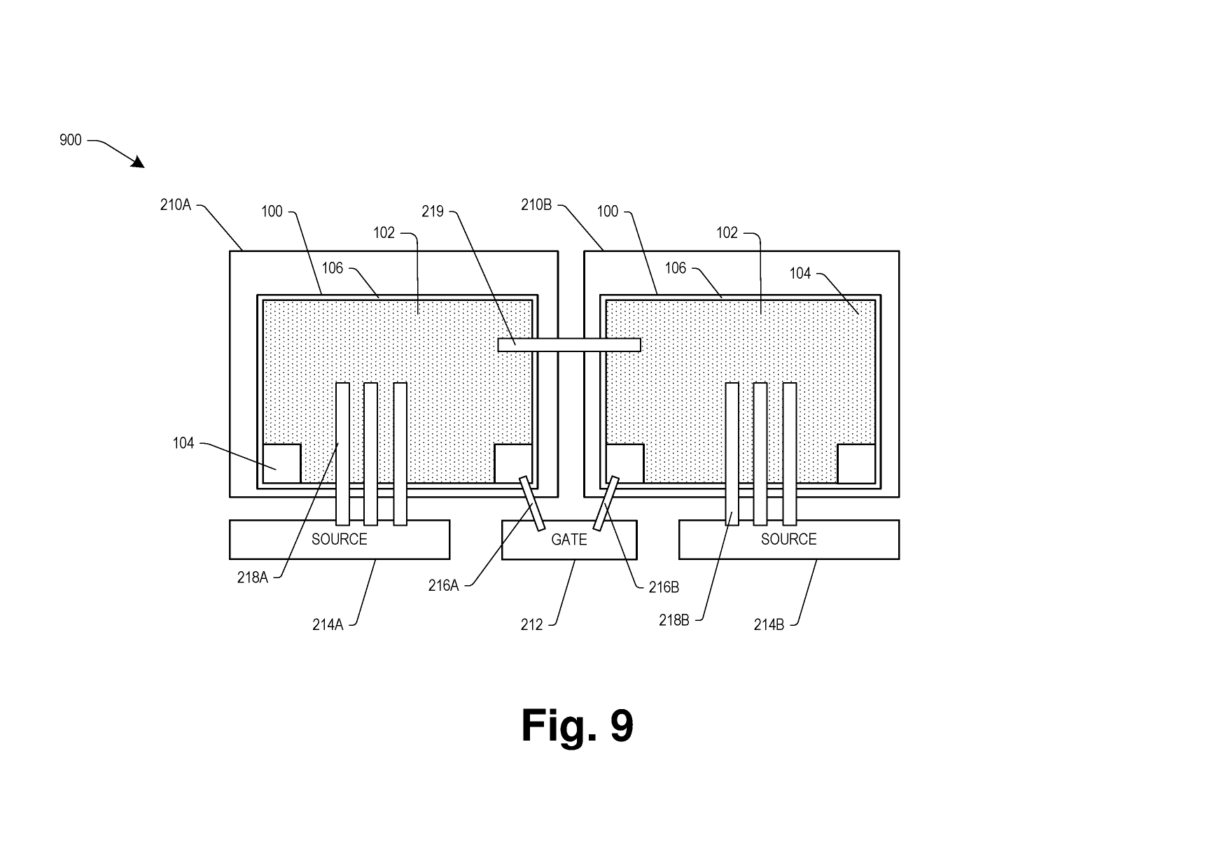

Referring to FIG. 9, a circuit board assembly 900 comprises semiconductor packages 210A, 210B including instances of the semiconductor device 100 interface with a gate pin 212 and source pins 214A, 214B such that the semiconductor devices 100 in the semiconductor packages 210A, 210B are interconnected and operated in parallel. In the embodiment of FIG. 9, the semiconductor devices 100 each comprises two gate pads 104 connected by the gate ring 106. Gate interconnects 216A, 216B connect the gate pin 212 to the gate pads 104 of the semiconductor devices 100 in the semiconductor packages 210A, 210B. In some embodiments, source interconnects 218A, 218B connect the source pins 214A, 214B to the respective source pads 102 of the semiconductor devices 100 in the semiconductor packages 210A, 210B. In some embodiments, an additional source interconnect 219 directly connects the respective source pads 102 of the semiconductor devices 100 in the semiconductor packages 210A, 210B.

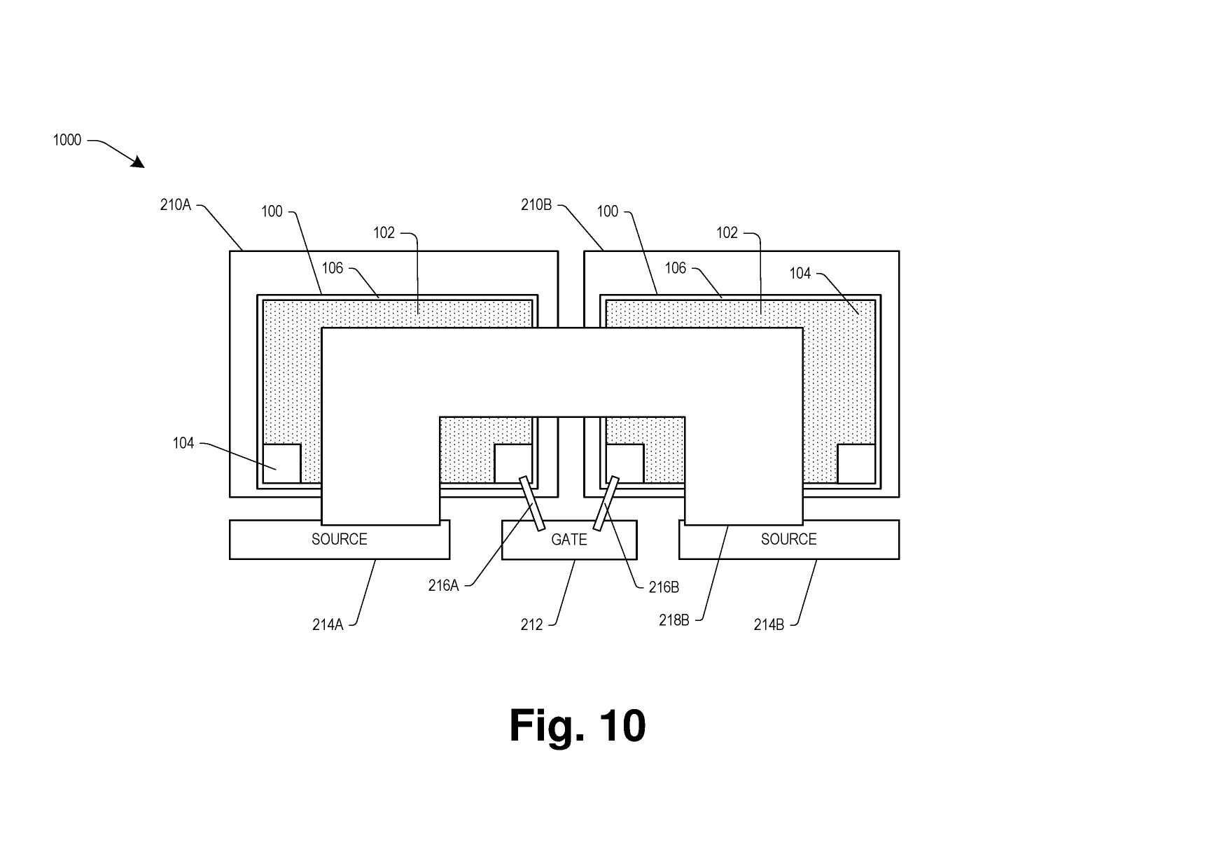

Referring to FIG. 10, a circuit board assembly 1000 comprises the source interconnects 218A, 218B, 219 illustrated in FIG. 9 are replaced by a source interconnect clip 218P contacting and interconnecting the respective source pads 102 of the semiconductor devices 100 in the semiconductor packages 210A, 210B.

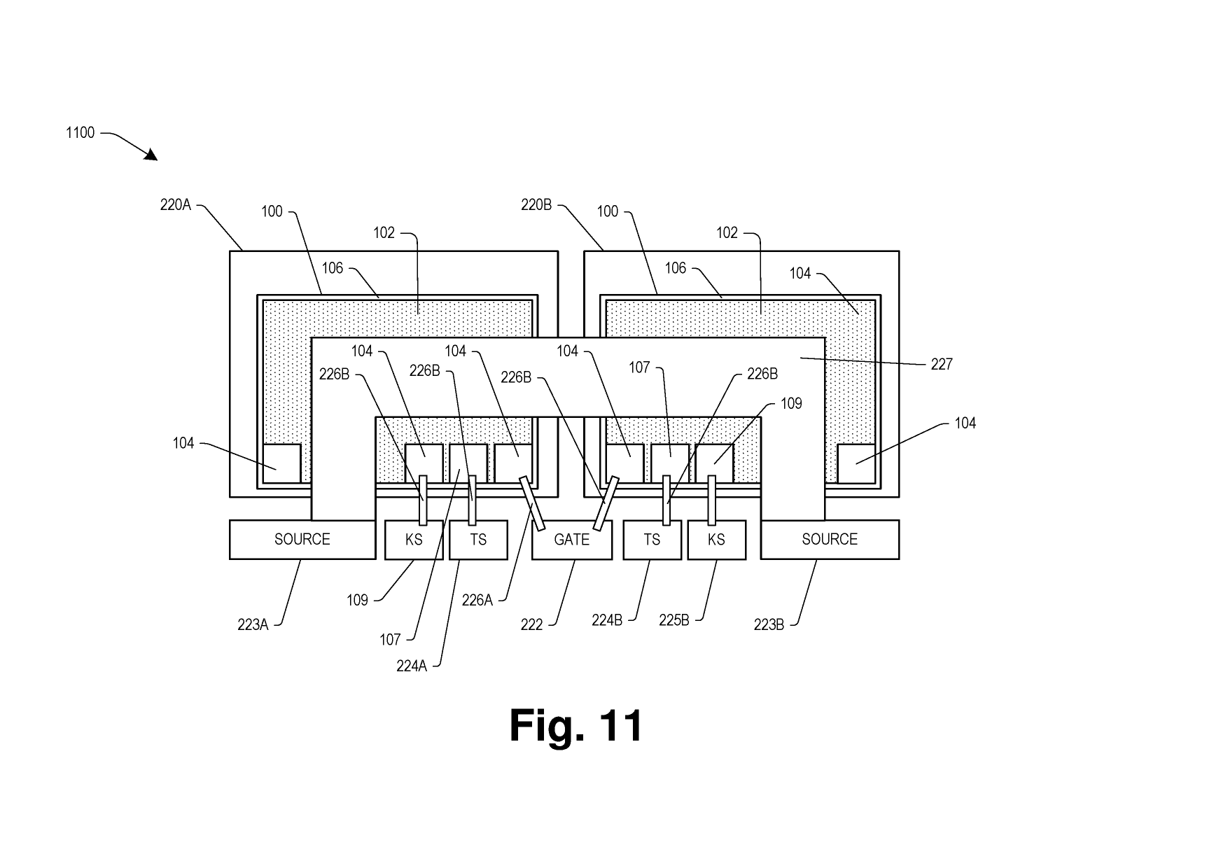

Referring to FIG. 11, a circuit board assembly 1100 comprises semiconductor packages 220A, 220B including instances of the semiconductor device 100 interface with a gate pin 222, source pins 223A, 223B, TS pins 224A, 224B, and Kelvin sense (KS) pins 225A, 225B, and a such that the semiconductor devices 100 in the semiconductor packages 220A, 220B are interconnected and operated in parallel. In the embodiment of FIG. 11, the semiconductor devices 100 each comprises two gate pads 104 connected by the gate ring 106, a TS pad 107, and a KS pad 109. Gate interconnects 226A, 226B connect the gate pin 222 to the gate pads 104 of the semiconductor devices 100 in the semiconductor packages 220A, 220B. In some embodiments, a source clip 227 connects the source pins 223A, 223B to the respective source pads 102 of the semiconductor devices 100 in the semiconductor packages 220A, 220B. TS interconnects connect the TS pins 224A, 224B to the respective TS pads 107 of the semiconductor devices 100 in the semiconductor packages 220A, 220B. KS interconnects connect the KS pins 225A, 225B to the respective KS pads 109 of the semiconductor devices 100 in the semiconductor packages 220A, 220B. The number of gate pads 104 on the semiconductor devices 100 may vary. The number or position of TS pads 107 or KS pads 109 may vary or one or more may be omitted. The source clip 227 may be replaced by interconnects between the source pads 102 and the source pins and an interconnect between the source pads 102 (as shown in FIG. 9). The shape of the source clip 227 may vary. For example if only one source pin 223A, 223B is provided, the source clip 227 may have a shape similar to the source clip 190C illustrated in FIG. 8.

Providing flexibility for multi-chip products by providing multiple gate pads 104 interconnected by a gate ring 106 allows package orientations to be changed, shortest signal paths to be selected, multiple signal paths or package-to-package interconnects to be provided to decrease propagation delay, reduce the parasitic impact of the gate ring 106, reduce asymmetric source bonding to ground, provide flexibility to meet manufacturability and design rules, and other advantages.

According to some embodiments, a device is provided. The device comprises a transistor comprising a gate electrode, a first gate pad connected to the gate electrode, a second gate pad connected to the gate electrode, and a first gate ring connecting the first gate pad and the second gate pad.

According to some embodiments, the first gate ring and the gate electrode comprise polysilicon.

According to some embodiments, the device comprises a second gate ring over the first gate ring, wherein the first gate ring is connected to the second gate ring, the first gate ring and the gate electrode are formed in a first layer, and the second gate ring, the first gate pad, and the second gate pads are formed in a second layer over the first layer.

According to some embodiments, the device comprises a dielectric layer between the first gate ring and the second gate ring.

According to some embodiments, the device comprises a first conductive via in the dielectric layer connecting the gate electrode to the first gate pad, and a second conducive via in the dielectric layer connecting the first gate ring to the second gate ring.

According to some embodiments, the device comprises a protective layer over the gate ring.

According to some embodiments, the device comprises a gate interconnect formed over the protective layer and connecting the first gate pad and the second gate pad.

According to some embodiments, the device comprises a third gate pad connected to the first gate ring and the gate electrode, and a fourth gate pad connected to the first gate ring and the gate electrode.

According to some embodiments, the device comprises a circuit board assembly, comprising a gate pin, a first gate interconnect connecting the first gate pad and the gate pin, and a second gate interconnect connecting the second gate pad and the gate pin.

According to some embodiments, the device comprises a temperature sense pad, and a circuit board assembly comprising a temperature sense pin, and a temperature sense interconnect connecting the temperature sense pad and the temperature sense pin.

According to some embodiments, a circuit board assembly is provided. The circuit board assembly comprises a first semiconductor package comprising a first semiconductor die, the first semiconductor die comprises a first gate pad, a second gate pad, and a first gate ring connecting the first gate pad to the second gate pad. The circuit board assembly comprises a second semiconductor package comprising a second semiconductor die, the second semiconductor die comprises a third gate pad, a fourth gate pad, and a second gate ring connecting the third gate pad to the fourth gate pad. The circuit board assembly comprises a gate pin, and a gate interconnect connecting the gate pin to the first gate pad and the third gate pad.

According to some embodiments, the gate interconnect comprises a first interconnect connecting the gate pin to the first gate pad, and a second interconnect connecting the gate pin to the third gate pad.

According to some embodiments, the gate interconnect comprises a first interconnect connecting the gate pin to the first gate pad, and a second interconnect connecting the first gate pad to the third gate pad.

According to some embodiments, the first semiconductor die comprises a first source pad, the second semiconductor die comprises a second source pad, and the circuit board assembly comprises a first source pin, and a source interconnect connecting the first source pin to the first source pad and the second source pad.

According to some embodiments, the source interconnect comprises a first interconnect connecting the first source pin to the first source pad, and a second interconnect connecting the first source pin to the second source pad.

According to some embodiments, the source interconnect comprises a first interconnect connecting the first source pin to the first source pad, and a second interconnect connecting the first source pad to the second source pad.

According to some embodiments, the source interconnect comprises a clip connecting the first source pin to the first source pad and connecting the first source pad to the second source pad.

According to some embodiments, the circuit board assembly comprises a second source pin, wherein the source interconnect comprises a clip connecting the first source pin to the first source pad, connecting the first source pad to the second source pad, and connecting the second source pad to the second source pin.

According to some embodiments, the first semiconductor die comprises a first sense pad, the second semiconductor die comprises a second sense pad, and the circuit board assembly comprises a first sense pin, a second sense pin, a first sense interconnect connecting the first sense pin to the first sense pad, and a second sense interconnect connecting the second sense pin to the second sense pad.

According to some embodiments, a method is provided. The method comprises mounting a first semiconductor die in a first semiconductor package, the first semiconductor die comprises a first gate pad, a second gate pad, and a first gate ring connecting the first gate pad to the second gate pad. The method comprises mounting a second semiconductor die in a second semiconductor package, the second semiconductor die comprises a third gate pad, a fourth gate pad, and a second gate ring connecting the third gate pad to the fourth gate pad. The method comprises connecting a gate pin to the first gate pad and the third gate pad.

It may be appreciated that combinations of one or more embodiments described herein, including combinations of embodiments described with respect to different figures, are contemplated herein.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

Any aspect or design described herein as an "example" is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term "or" is intended to mean an inclusive "or" rather than an exclusive "or". That is, unless specified otherwise, or clear from context, "X employs A or B" is intended to mean any of the natural inclusive permutations. That is, if X employs A; X employs B; or X employs both A and B, then "X employs A or B" is satisfied under any of the foregoing instances. In addition, the articles "a" and "an" as used in this application and the appended claims may generally be construed to mean "one or more" unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms "includes", "having", "has", "with", or variants thereof are used in either the detailed description or the claims, such terms are intended to be inclusive in a manner similar to the term "comprising."

While the subject matter has been described with reference to illustrative embodiments, this description is not intended to be construed in a limiting sense. Various modifications and combinations of the illustrative embodiments, as well as other embodiments of the present disclosure, will be apparent to persons skilled in the art upon reference to the description. It is therefore intended that the appended claims encompass any such modifications or embodiments.

What is claimed is:

1. A device, comprising:
a transistor comprising a gate electrode;
a first gate pad connected to the gate electrode;
a second gate pad connected to the gate electrode; and
a first gate ring connecting the first gate pad and the second gate pad.

2. The device of claim 1, wherein:
the first gate ring and the gate electrode comprise polysilicon.

3. The device of claim 1, comprising:
a second gate ring over the first gate ring, wherein:
the first gate ring is connected to the second gate ring;
the first gate ring and the gate electrode are formed in a first layer; and
the second gate ring, the first gate pad, and the second gate pads are formed in a second layer over the first layer.

4. The device of claim 3, comprising:
a dielectric layer between the first gate ring and the second gate ring.

5. The device of claim 4, comprising:
a first conductive via in the dielectric layer connecting the gate electrode to the first gate pad; and
a second conducive via in the dielectric layer connecting the first gate ring to the second gate ring.

6. The device of claim 1, comprising:
a protective layer over the gate ring.

7. The device of claim 6, comprising:
a gate interconnect formed over the protective layer and connecting the first gate pad and the second gate pad.

8. The device of claim 1, comprising:
a third gate pad connected to the first gate ring and the gate electrode; and
a fourth gate pad connected to the first gate ring and the gate electrode.

9. The device of claim 1, comprising:
a circuit board assembly, comprising:
a gate pin;
a first gate interconnect connecting the first gate pad and the gate pin; and
a second gate interconnect connecting the second gate pad and the gate pin.

10. The device of claim 1, comprising:
a temperature sense pad; and
a circuit board assembly, comprising:
a temperature sense pin; and
a temperature sense interconnect connecting the temperature sense pad and the temperature sense pin.

11. A circuit board assembly, comprising:
a first semiconductor package comprising a first semiconductor die, the first semiconductor die comprising:
a first gate pad;
a second gate pad; and
a first gate ring connecting the first gate pad to the second gate pad;
a second semiconductor package comprising a second semiconductor die, the second semiconductor die comprising:
a third gate pad;
a fourth gate pad; and
a second gate ring connecting the third gate pad to the fourth gate pad;
a gate pin; and
a gate interconnect connecting the gate pin to the first gate pad and the third gate pad.

12. The circuit board assembly of claim 11, wherein:
the gate interconnect comprises:
a first interconnect connecting the gate pin to the first gate pad; and
a second interconnect connecting the gate pin to the third gate pad.

13. The circuit board assembly of claim 11, wherein:
the gate interconnect comprises:
a first interconnect connecting the gate pin to the first gate pad; and
a second interconnect connecting the first gate pad to the third gate pad.

14. The circuit board assembly of claim 11, wherein:
the first semiconductor die comprises a first source pad;
the second semiconductor die comprises a second source pad; and
the circuit board assembly comprises:
a first source pin; and
a source interconnect connecting the first source pin to the first source pad and the second source pad.

15. The circuit board assembly of claim 14, wherein:
the source interconnect comprises:
a first interconnect connecting the first source pin to the first source pad; and
a second interconnect connecting the first source pin to the second source pad.

16. The circuit board assembly of claim 14, wherein:
the source interconnect comprises:
a first interconnect connecting the first source pin to the first source pad; and
a second interconnect connecting the first source pad to the second source pad.

17. The circuit board assembly of claim 14, wherein:
the source interconnect comprises:
a clip connecting the first source pin to the first source pad and connecting the first source pad to the second source pad.

18. The circuit board assembly of claim 14, comprising:
a second source pin, wherein
the source interconnect comprises:
a clip connecting the first source pin to the first source pad, connecting the first source pad to the second source pad, and connecting the second source pad to the second source pin.

19. The circuit board assembly of claim 11, wherein:
the first semiconductor die comprises a first sense pad;
the second semiconductor die comprises a second sense pad; and
the circuit board assembly comprises:
a first sense pin;
a second sense pin;
a first sense interconnect connecting the first sense pin to the first sense pad; and
a second sense interconnect connecting the second sense pin to the second sense pad.

20. A method, comprising:
mounting a first semiconductor die in a first semiconductor package, the first semiconductor die comprising:
a first gate pad;
a second gate pad; and
a first gate ring connecting the first gate pad to the second gate pad;
mounting a second semiconductor die in a second semiconductor package, the second semiconductor die comprising:
a third gate pad;
a fourth gate pad; and
a second gate ring connecting the third gate pad to the fourth gate pad; and
connecting a gate pin to the first gate pad and the third gate pad.
